(19) United States
(12) Patent Application Publication
(10) Pub. No.: US 2021/0380402 A1
(43) Pub. Date: Dec. 9, 2021

(54) MEMS SYSTEM

(71) Applicant: Fraunhofer-Gesellschaft zur Foerderung der angewandten Forschung e.V., Munich (DE)

(72) Inventors: Malte Florian NIEKIEL, Itzehoe (DE); Fabian LOFINK, Itzehoe (DE); Thomas LISEC, Itzehoe (DE)

(21) Appl. No.: 17/353,305

(22) Filed: Jun. 21, 2021

Related U.S. Application Data
(63) Continuation of application No. PCT/EP2019/086755, filed on Dec. 20, 2019.

(30) Foreign Application Priority Data
Dec. 21, 2018 (DE) 102018222845.0

(51) Int. Cl. B81B 5/00; H01F 41/30; H01F 7/02

(52) U.S. Cl. CPC B81B 5/00; H01F 41/30; B81B 2201/042; B81B 2201/0257; H01F 7/02

(57) ABSTRACT

A MEMS system includes a first permanent-magnetic microstructure and a second permanent-magnetic microstructure. The first permanent-magnetic microstructure is movable along a first direction. The second permanent-magnetic microstructure is arranged to be spaced apart from the first permanent-magnetic microstructure, wherein, by moving the first permanent-magnetic microstructure along the first direction, the second permanent-magnetic microstructure or one or more elements of the second permanent-magnetic microstructure are either moved or actuated in a second direction or undergo rotation.

### CROSS-REFERENCE TO RELATED APPLICATIONS

This application is a continuation of copending International Application PCT/EP2019/086755, filed Dec. 20, 2019, which is incorporated herein by reference in its entirety, and additionally claims priority from German Application No. 102018222845.0, filed Dec. 21, 2018, which is also incorporated herein by reference in its entirety.

### BACKGROUND OF THE INVENTION

Embodiments of the present invention relate to a MEMS system and to a corresponding manufacturing method. Embodiments relate to a MEMS system comprising two permanent-magnetic microstructures. Further embodiments relate to magnetic coupling for force transmission in micromechanical systems.

Almost all micromechanical systems are based on generating mechanical forces (actuators) or their conversion into electrical signals (sensors). The established drive concepts allow effective force generation and/or transmission either in the component plane (laterally) or perpendicular to it (vertically). For example, an electrostatic comb drive is suitable for lateral force generation, while a piezoelectric bending beam can be applied for vertical deflections. These concepts cannot be transferred to the respective other direction, or only with great difficulty. For example, a comb drive with vertical fingers or a lateral piezo bending actuator is hardly feasible with existing technological processes. Similar examples can be found in the field of sensing, where different detection mechanisms perform differently in different directions. This significantly limits the possible applications of microelectromechanical systems (MEMS). It would therefore be extremely attractive to be able to effectively transform deflections and/or forces in MEMS in any directions.

In MEMS, mainly electrostatic and piezoelectric drives are used. The direction of action of the force or deflection is basically predetermined by the geometry of the drive. For example, different geometries have been developed for electrostatic actuators to cover different directions of action. Lateral comb drives [1], vertical comb drives [2], tilting comb drives [3], rotating comb drives [4] and parallel plate drives [5, 6] are known. Although they are all based on the same physical effect, i.e. the electrostatic attraction or repulsion of two electrode surfaces, the effect is very different. For example, the lateral comb drive allows large deflections of over 100 μm thanks to long finger electrodes [7]. Limited by the planar manufacturing processes of semiconductor technology, the deflection of vertical, tilting or rotating comb drives is smaller by an order of magnitude. Piezoelectric drives, on the other hand, which are mostly based on bending beams, are well suited especially for vertical deflections or tilting. Lateral piezoelectric drives are difficult to implement in this case.

Previous attempts to change the directions of action in microelectromechanical systems and/or to amplify the force or deflection are largely based on mechanical lever structures. Examples include bulging structures for amplifying the deflection of drives [8, 9], but also optimized lever systems such as those used to increase the sensitivity of acceleration sensors [10, 11]. In these examples, the effective direction remains within the component plane. However, vertically acting lever structures can also be found. In [12], the vertical deflection of a tilting comb drive is transmitted to a micromirror by a lever structure. Another form of force/deflection conversion is microtransmission based on Si gears [13]. However, their practical application fails because of the extraordinarily fast wear due to friction. Also to be mentioned are mechanical bandpass filters based on coupled oscillators. Coupling for the transmission of forces between the oscillating masses may be solved by mechanical springs [14, 15], more rarely also by electrostatic force coupling [16].

The transmission of forces or deflections from an external drive into a micromechanical system is solved, for example, by contact mechanics. In [17], the vertical stroke of a stepper motor is applied in a haptic display. [18] describes a piezoelectric harvester in which a MEMS bending transducer is directly mechanically actuated by a gear. All these transformations entail significant frictional wear due to the direct contact of the micromechanical structures with conventionally fabricated components. Therefore, there is need for an improved approach.

The object underlying the present invention is to create a concept for force or motion transmission that is optimized in terms of wear and transmittable force.

### SUMMARY

According to an embodiment, a MEMS system may have: a first permanent-magnetic microstructure movable along a first direction; a second permanent-magnetic microstructure arranged to be spaced apart from the first permanent-magnetic microstructure, wherein, by moving the first permanent-magnetic microstructure along the first direction, the second permanent-magnetic microstructure or one or more elements of the second permanent-magnetic microstructure are either moved or actuated in a second direction or undergo rotation; wherein the first permanent-magnetic microstructure is formed by a first array having a plurality of permanent-magnetic elements; or wherein the second permanent-magnetic microstructure is formed by a second array having a plurality of the permanent-magnetic elements; and wherein the plurality of the permanent-magnetic elements of the first or second array are rigidly connected to one another so that they are similarly moved or actuated as a result of a movement of the first permanent-magnetic microstructure along the second direction.

According to another embodiment, a method of manufacturing an inventive MEMS system as mentioned above may have the step of: agglomeration of powder by means of atomic layer deposition or by means of deposition to form the first and/or the second permanent-magnetic microstructure or to form the one or more elements of the first and/or the second permanent-magnetic microstructure.

Embodiments of the present invention provide a MEMS system having at least two permanent-magnetic microstructures. The first permanent-magnetic microstructure is movable in a first direction (e.g. along the substrate plane). The second permanent-magnetic structure is arranged to be spaced apart from the first permanent-magnetic structure and is supported such that, by moving the first permanent-magnetic microstructure in the first direction, the second permanent-magnetic microstructure or one or more elements of the second permanent-magnetic microstructure are actuated or moved in the second direction (an actuation being understood to mean, in the simplest case, simple force coupling). Alternatively, it would also be conceivable that a rotation of the second permanent-magnetic microstructure or elements of the permanent-magnetic microstructure is caused as a result of the movement.

At this point, it should be noted that, according to embodiments, a permanent-magnetic structure (first and/or second) is understood to be both a structure with only one element (single magnet) and one with multiple magnetic elements (e.g. fingers) forming a magnet array. According to an embodiment, the first permanent-magnetic structure may comprise a plurality of permanent-magnetic elements (e.g. multiple magnet fingers or elongated elements, or even a two-dimensional array of cube-shaped magnets) arranged to form an array. According to a further embodiment, the second permanent-magnetic structure may comprise a plurality of permanent-magnetic elements (e.g. multiple magnet fingers or elongated elements or also a two-dimensional array of cube-shaped magnets) arranged to form an array. Here, for example, the array may be designed such that the first and/or second permanent-magnetic structure is shaped as a kind of comb with several elements/fingers spaced apart from one another. According to embodiments, this comb can have a repeat spacing of the individual elements of 10 to 300 μm. Depending on the coupling of the permanent-magnetic elements (rigid coupling or individual coupling), the movement of the permanent-magnetic microstructure is to be understood in such a way that an actuation (in the sense of force application) or a movement of the entire second permanent-magnetic microstructure or of the individual elements of the second permanent-magnetic microstructure is effected. This movement can be either a longitudinal movement, e.g. perpendicular to the substrate plane or also parallel to the substrate plane (i.e. parallel to the first direction), or a rotation.

Embodiments of the present invention are based on the realization that microstructures with miniaturized permanent magnets can be magnetically coupled to one another so that the microstructures are subjected to a force or deflected (in the sense of translationally or rotationally moved) as a result of a movement of other permanent magnets with whose magnetic field they interact. In other words, this means that the permanent-magnetic structures or elements of the permanent-magnetic structures interact due to their integrated micro-magnets so as to enable contactless transmission of (as high as possible) forces (with and without movement), e.g. up to 100 μN or up to 1 mN or up to 10 mN or even up to 500 mN, by means of magnetic coupling. This contactless transmission allows in particular to bridge (larger) distances (up to 100 μm or up to 1 mm or up to 5 mm or up to 10 mm) within the micromechanical device/system. Depending on the exact implementation, an equally oriented movement of the two permanent-magnetic microstructures or a change in direction can be effected. Force coupling is contactless. There are no wear effects at mechanical contact points, which in the case of micromechanical structures lead to a particularly rapid failure of the component. Another advantage is that force coupling by means of permanent magnets is based on a passive effect. This means that no additional energy has to be applied to maintain this force coupling.

According to embodiments, the permanent-magnetic elements of the magnetically coupled permanent-magnetic microstructures may be achieved either by attractive magnetic forces (parallel magnetization) (so that opposite poles of the two permanent-magnetic microstructures face each other) or by repulsive magnetic forces (opposite magnetization, so that always equal magnetic poles of the permanent-magnetic structures face each other). Alternatively, there may also be a vertical orientation, i.e. that the magnetization direction of the first permanent-magnetic microstructure extends, for example, perpendicularly (90° or in the range of 80° to 100°).

According to embodiments, the first permanent-magnetic structure or its elements are coupled or connected to a micromechanical actuator (part of the MEMS system), wherein the micromechanical actuator is configured to move the first permanent-magnetic structure along the first direction. For example, the actuator may be a vertically acting bending beam embedded in a substrate. According to further embodiments, the two permanent-magnetic structures are formed within a substrate. Here, for example, the first direction may extend laterally along the substrate, while the second direction may extend perpendicularly to the substrate or laterally to the substrate. Of course, an orientation rotated by 90 degrees is also conceivable.

According to embodiments, lateral displacements/forces can thus be transferred into vertical deflections/forces or tilting movements, but also vertical displacements/forces into lateral deflections/forces. This is particularly important due to the planar technology underlying microsystem technology. When combining a structure movable along a first direction with a structure movable along a second direction, where the second direction differs from the first direction, e.g. by 90 degrees, a factor of about 2 between the input force and the resulting output force can be achieved by this lateral-vertical coupling in the case of arrays. In this respect, there is an advantage in the fact that force (or power) transmission can also take place here.

According to embodiments, different position variants can be provided for the first and the second permanent-magnetic structure or the elements of the first and second permanent-magnetic structures. According to a first variant, for example, it is possible that the second permanent-magnetic structure or its elements are supported in such a way that they can only rotate about an axis of rotation (e.g. perpendicular to the first direction). Alternatively, it would also be conceivable that the support (or bearing) is provided such that the first permanent-magnetic structure is restricted in a movement perpendicular to the first direction. With respect to the second permanent-magnetic structure, it should be noted that, according to embodiments, the latter or its elements are restricted in their movement perpendicular to the second direction or, alternatively, are restricted perpendicular to the first direction. According to embodiments, both the first and the second permanent-magnetic structure or elements thereof extend along a third direction that is perpendicular to the first and second directions. Returning to the variant with the rotating elements, it should be noted at this point that the support can also be oriented such that the elements or the structure are restricted in their movement in the first, second and third directions, while rotation, e.g. about a vector extending along the third direction, is permitted.

According to embodiments, during the movement of the two structures or also during the rest state, the two permanent-magnetic structures are spaced apart from each other. The distance is maintained over the movement by the two permanent-magnetic structures magnetically influencing each other accordingly. According to embodiments, the distance may be in a range from 1 μm to 5 mm, advantageously between 5 μm and 2000 μm or particularly advantageously between 10 and 1000 μm. With regard to the dimensioning of the permanent-magnetic structures or the individual elements of the permanent-magnetic structures, it should be noted that these can have an edge length between 10 μm and 2 mm, advantageously between 20 μm and 1000 μm or particularly advantageously between 30 μm and 800 μm.

As mentioned above, according to embodiments, each permanent-magnetic structure can be designed as an array, i.e. comprising a plurality of elements. The use of arrays of permanent-magnetic microstructures allows to minimize the displacement used for force transmission while maintaining high transmitting forces. Thus, the use of arrays allows force transmission in the area, the effect depending on the shape, size and arrangement of the micromagnets in the arrays involved.

With respect to the coupling of the plurality of permanent-magnetic elements, it should be noted that these can be either rigid or individual such that the elements are moved in a similar manner or undergo a similar rotation as a result of a movement of the first permanent-magnetic structure along the second direction. Alternatively, of course, it would be conceivable for the permanent-magnetic elements to be individually supported such that the plurality of permanent-magnetic elements undergo individual movement in response to the movement of the first permanent-magnetic structure. Here, either an individual rotation and/or an individual longitudinal movement and/or an individual vertical movement may be meant. With respect to the elements of the permanent-magnetic structure, it should be noted that these may have an equal shape in each permanent-magnetic structure according to an embodiment or may be different according to a further embodiment. According to one embodiment, the first permanent-magnetic structure comprises a singular number of permanent-magnetic elements, while the second permanent-magnetic structure comprises a plurality of permanent-magnetic elements facing one another. According to another embodiment, the first permanent-magnetic structure may comprise a plurality opposing the plurality of permanent-magnetic elements of the second structure. Advantageously, the number of elements of the first and second permanent-magnetic structures is the same.

Since the permanent-magnetic structures are spaced apart from one another, it would be conceivable for one of the two permanent-magnetic structures to be encapsulated with respect to the other of the two permanent-magnetic structures. For example, the second permanent-magnetic structure could be disposed in a chamber. This allows the chamber to be filled with a special fluid or gas or to be evacuatable.

Another embodiment relates to a manufacturing method of the MEMS system explained above. The manufacturing method comprises the central step of agglomerating powder by means of atomic layer deposition or by means of another type of deposition to form the first and/or the second permanent-magnetic structure (e.g. in a substrate), or to form the one or more elements of the first and/or the second permanent-magnetic structure.

### BRIEF DESCRIPTION OF THE DRAWINGS

Embodiments of the present invention will be explained with reference to the accompanying drawings, in which:

FIG. 1a-2b show schematic representations of conventional MEMS systems using micromagnetic elements, for comparison purposes;

FIG. 3 shows a schematic diagram of a MEMS system with two permanent-magnetic microstructures, according to a basic embodiment;

FIG. 4 shows a schematic representation of magnetic coupling using two arrays, according to extended embodiments;

FIG. 5 shows a schematic diagram illustrating the resulting force curve of the embodiment from FIG. 4;

FIGS. 6a-6d show schematic representations illustrating the possible directions of force action and movement, according to embodiments;

FIGS. 7a-7b show schematic representations of possible directions of force action and resulting movements, according to embodiments;

FIG. 8 shows schematic representations of two permanent-magnetic microstructures implemented as an array, according to embodiments;

FIG. 9 shows a schematic representation of two permanent-magnetic microstructures implemented as an array, for illustrating individual coupling, according to further embodiments;

FIG. 10 shows a schematic representation of a permanent-magnetic structure implemented as an array, in combination with a permanent-magnetic structure implemented as an element, according to further embodiments;

FIG. 11 shows a schematic representation of two permanent-magnetic structures configured as an array, for illustrating magnetization in opposite directions, according to embodiments; and

FIGS. 12a-12b show a schematic representation of magnetic force coupling within one and the same medium as well as in different media, according to further embodiments.

### DETAILED DESCRIPTION OF THE INVENTION

Before explaining embodiments of the present invention with reference to the accompanying drawings, it should be noted that elements and structures of equal effect are provided with same reference signs so that the description thereof is mutually applicable or interchangeable.

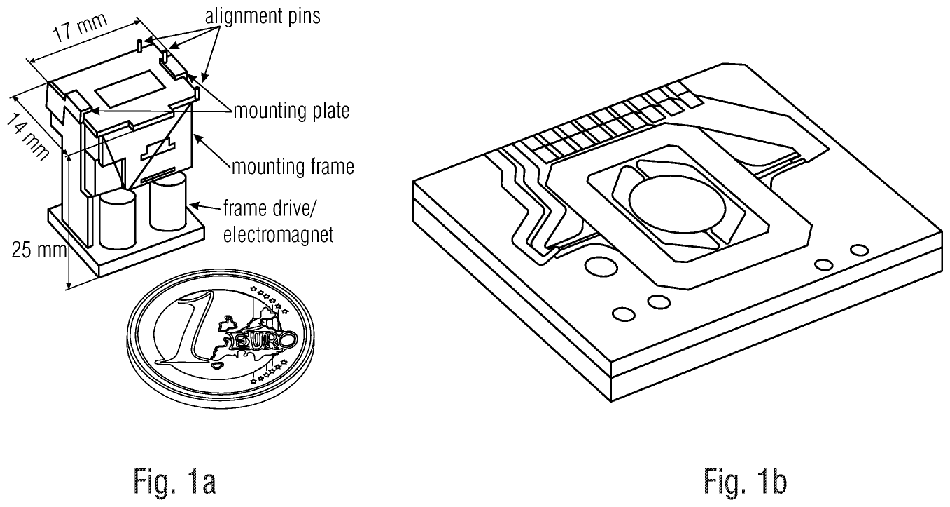

As explained above, embodiments are based on micromechanical structures or elements of micromechanical structures being magnetically coupled to one another so that they can transmit forces from one micromechanical structure to another micromechanical structure and/or they influence one another in their movement. Since such embodiments are based on the fact that micromechanical structures are implemented to be permanent-magnetic, a brief overview of the contactless magnetic force transfer elements already in use is given below. In MEMS systems, mainly hybrid-mounted or external permanent magnets in combination with coils have been used for direct force generation [19, 20]. Such components are shown in FIGS. 1a and 1b.

FIG. 1a shows a magnetically actuatable microscanner with a permanent magnet bonded to the bottom of the movable mirror structure and external coils (cf. [19]). FIG. 1b shows a magnetically actuatable microscanner with a planar structure integrated on the top side of the movable mirror structure and an external permanent magnet located in the package (cf. [20]).

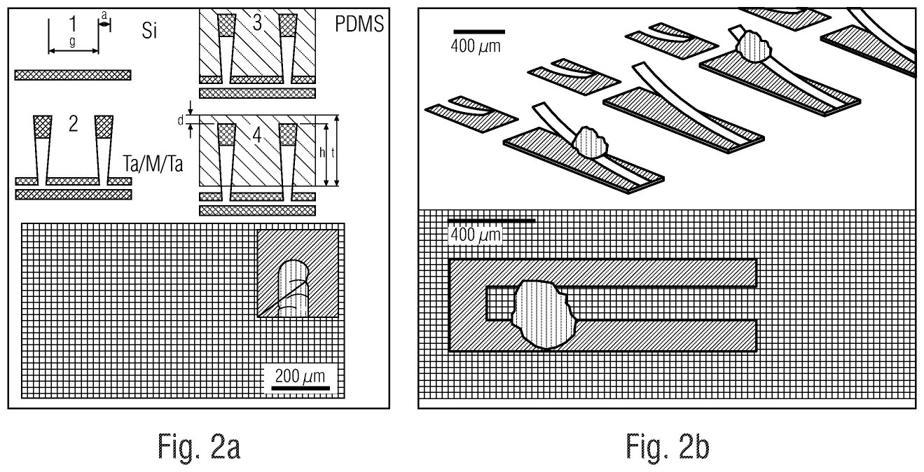

Since the magnetic force effect scales with the volume, the largest possible magnets are advantageous. Structures with edge lengths of a few ten to a few hundred micrometers would be ideal for MEMS. However, typical deposition processes in semiconductor technology are implemented for layers with a thickness of a few micrometers, so that the volume of magnets produced in this way remains very small. Classical sintering processes are only suitable for producing much larger structures. Recently, more work has therefore been done on manufacturing processes for micromagnets “with volume”. The deposition of thick NdFeB layers by sputtering or pulsed laser deposition (PLD) [21] should be mentioned. One problem is patterning such layers. In [22], this is solved by sputtering microcolumns with NdFeB and their subsequent transfer into a flexible polymer membrane, see FIG. 1a. External magnetic fields can be used to control the warping of such membranes. Another way of manufacturing micromagnets is to use pastes or solutions of magnetic particles and polymers as starting materials. In [23], a current sensor is presented consisting of a cantilever bending beam with a piezoelectric transducer and a micromagnet on the free end created by dispersion of a NdFeB powder-epoxy solution, see FIG. 2b. Structures of better defined shape can be created by introducing a magnetic powder-polymer composite into microforms. Due to the viscosity increasing with the powder content, smaller structures cannot be realized reproducibly. One way out is to fill the microforms with loose magnetic powder and then solidify it. In [24], a Parylene layer is used for this purpose. However, all polymer-based processes have significant disadvantages with respect to integration in MEMS due to the low thermal stability of the organic matrix material as well as the insufficient protection of the magnetic particles against corrosion effects.

FIG. 2a shows micromagnet arrays made of Si microcolumns with sputtered-on NdFeB transferred into a flexible polymer membrane [22]. FIG. 2b shows current sensors consisting of a piezoelectric bending beam with a micromagnet on the free-moving end produced by dispersion of a solution containing magnetic powder [23].

An attractive alternative to the previously mentioned methods is based on the agglomeration of loose powder by means of Atomic Layer Deposition (ALD) [25]. In this way, permanent-magnetic microstructures with edge lengths between 50 μm and 2000 μm could be generated on planar substrates for the first time in a reproducible manner and compatible with MEMS manufacturing processes. In [26], a piezoelectric vibrating harvester with a micromagnet array at the free-moving end of a bending beam is described. The device is actuated not only by vibrations or shocks, but also by variable magnetic fields caused, for example, by a moving external permanent magnet. Thanks to this, it is possible for the first time to generate energy from rotary motion with a MEMS device. An implementation based on conventional magnets and piezo actuators is disclosed in [27].

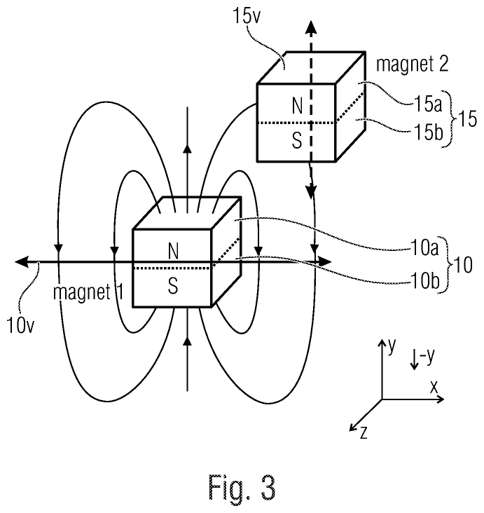

Based on this situation, an improvement can be created by the concept shown in FIG. 3. FIG. 3 shows two permanent-magnetic structures 10 and 15 that belong to or are part of a MEMS system that is not explained further. For example, the permanent-magnetic structure 10 may be movable by an actuator (not shown) of the MEMS system. In the simplest embodiment, both permanent-magnetic structures here comprise a single permanent-magnetic element, namely here the element 10 and 15, respectively. Both elements 10 and 15 are movable, for example, in a plane spanned by the two directions of movement 15v and 10v. This plane extends in the x-y direction. The orientation of the magnetization of each of the two permanent-magnetic elements 15 and 10 is indicated by the magnetic poles north and south, which are marked here by the reference signs 15a and 15b and 10a and 10b, respectively. Poles 15a and 15b and poles 10a and 10b, for example, are arranged such that both permanent-magnetic elements have a positive magnetization in the y direction. In other words, this means that north and south pole 10a/10b of the element 10 and north and south pole 15a and 15b of the element 15 are all arranged in the same plane. In this embodiment, the result is that the south pole 15b of the element 15 faces the north pole 10a of the element 10. This alignment is referred to as a parallel alignment of the magnets 10 and 15.

Both elements 10 and 15 are movable, the movability of element 10 being restricted such that it is movable substantially along the vector 10v (parallel to x), while movement in the y and/or z direction is restricted. The element 15 is movable along the vector 15v extending in the y direction, thus restricting movement in the z and/or x direction. According to embodiments, this restriction is performed by a support. In the following, the mode of operation of the permanent-magnetic structures 10 and 15 shown here will be explained. The use of permanent-magnetic microstructures 10 and 15 in MEMS enables the contactless transmission of forces, e.g. in the range of 1 μN to 1 mN. It is exemplarily assumed that the permanent-magnetic microstructure 10 is moved along the direction 10v, e.g. by an actuator integrated in the MEMS device. Due to magnetism, the permanent-magnetic microstructure 15 is then excited to move. This extends along the direction 15v due to magnetization alignment and support. The elements of the microstructures or the microstructures themselves interact without contact, so that distances in the range of a few micrometers to several millimeters can be bridged. The exact maximally transmittable force or the maximally bridgeable distance essentially depends on the dimensioning of the magnets 10 and 15. In the above ranges, for example, it was assumed that the individual magnets have an edge length in the range of 20 micrometers to 500 micrometers or arrays are formed from such permanent-magnetic elements. The greater the force to be transmitted or the greater the distance to be bridged, the larger the magnets 10 and 15 are generally dimensioned.

For the parallel magnetized cube-shaped magnets in FIG. 3, a strong force in the negative x direction and a weaker force in the negative y direction act on magnet 15 in the spatial position shown; in addition, a negative torque acts around the z axis. By shifting the magnet 10 relative to the magnet 15, the acting forces can be varied. For example, when arranged one above the other (same position on the x axis), no force acts on the magnet 15 in the x direction and a stronger force acts in the negative y direction. Also the torque around the z axis disappears for this arrangement. As shown in this example, the vertically acting attractive force as well as the transmitted torque can be varied in this way, e.g. by a relative lateral displacement of the two magnets with respect to each other. As already mentioned, the magnetic force effect scales with the volume of the magnets involved. According to [28], a magnetization of 500 mT is readily achievable for powder-based NdFeB micromagnets. In the case of a lateral displacement, as shown in FIG. 3, an edge length of the magnet of 50 μm and a distance between the magnets of 50 μm result in a maximum attractive force of 14 μN in the y direction. For magnets and edge lengths of 100 μm at a distance of 50 μm, the maximum attractive force in the y direction is already 166 μN. This example proves that even permanent magnets with a comparatively small volume allow the transmission of considerable forces over larger distances.

However, the displacement used for maximum modulation of the force also scales with its size. For an edge length of 50 μm, a displacement of at least 80 μm is used, for an edge length of 100 μm, a displacement of at least 135 μm. The optimum size of the micromagnets is therefore also determined by the displacement available (specified by the actuator used). In order to be able to transmit the greatest possible forces even with small magnets or small displacements, using arrays of permanent-magnet microstructures is an option.

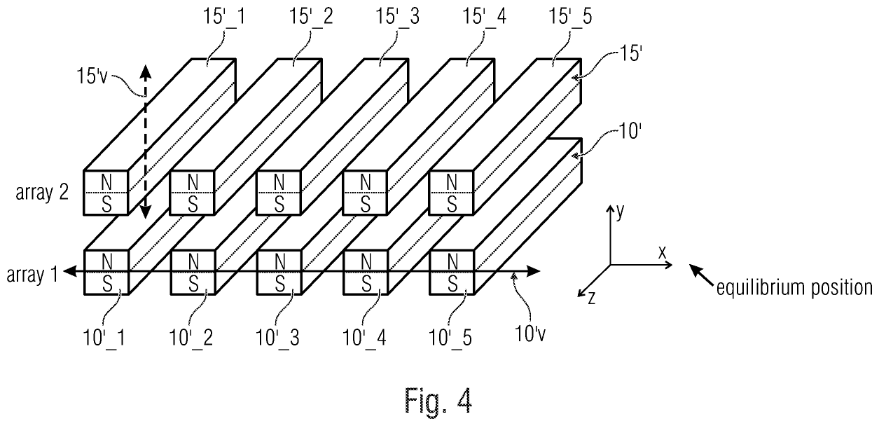

An example of such a combination is shown in FIG. 4. FIG. 4 shows two interacting permanent-magnetic structures 10′ and 15′. Both permanent-magnetic structures are arrays implemented from, for example, 5 elements 15′_1 to 15′_5 and 10′_1 to 10′_5 arranged next to one another in a comb shape in this case. The respective five fingers 10′_1 to 10′_5 and 15′_1 to 15′_5 are opposite each other, again assuming a parallel orientation of the magnetization. Within each array 10 and 15, the orientation of all elements 10′-′_1 to 10′_5 and 15′_1 to 15′_5, respectively, is the same. A lateral displacement (cf. vector 10′v) of the array 10 can be used to modulate the force action in the y direction (cf. vector 15′v). The array arrangement 10′/15′ increases the transmission of the force without entailing a larger displacement of the array 10. Extending the micromagnets in the z direction to form cuboid micromagnets 10′_1 to 10′_5 and 15′_1 to 15′_5 (optional feature) further increases the force without affecting the displacements used.

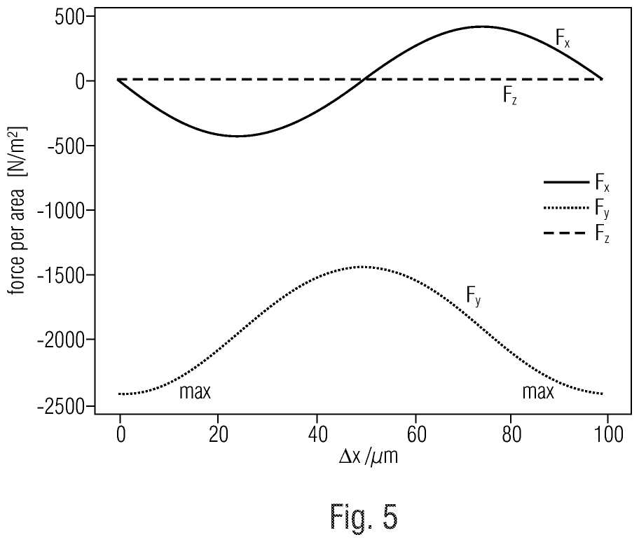

The result of the numerical modulation of the array arrangement 10′/15′ from FIG. 4 is shown in FIG. 5. For the calculations, magnetic fingers of infinite length with square cross-section (50 μm edge length) were assumed, and the spacing of the two arrays 10′/15′ was kept at 50 μm. Using periodic boundary conditions, the behavior of infinite arrays was simulated, therefore the forces were normalized to the array area used. As shown in FIG. 5, due to symmetry, the forces vary periodically with twice the edge length of the cube-shaped magnets. In the equilibrium position (Δx=0), the magnets 10′_1 to 10′_5/15′_1 to 15′_5 are aligned with one another in the y direction and the maximum attractive force of 2420 N/m² is applied. When the array 15′ is deflected from this equilibrium position to a displacement of Δx=50 μm, a restoring force of up to 430 N/m² acts in the negative x direction. The attractive force in the y direction decreases due to this displacement until it reaches its lowest value of 1445 N/m² at Δx=50 μm. This is an unstable position, since a further displacement in the x direction leads to a forward driving force in the x direction, which in turn reaches up to 430 N/m². At a displacement of Δx=100 μm, the next stable position is reached, which corresponds to the equilibrium position shifted by one period.

According to these results, a lateral displacement of max. 50 μm and a lateral force of up to 430 N/m² can thus modulate a vertical force by up to 975 N/m². The force is thus amplified by a factor of approx. 2. In the technical implementation, the suspension and guidance of the arrays are of particular importance. While the spring stiffness in the direction of lateral displacement should be chosen to be small so as not to have to apply unnecessarily high forces, the vertical spring stiffness should be chosen to be as stiff as possible so as not to lose force or deflection in the vertical direction due to the flexibility of the array, which is assumed to be fixed here. In addition, the non-driven array is prevented from moving along in the drive direction.

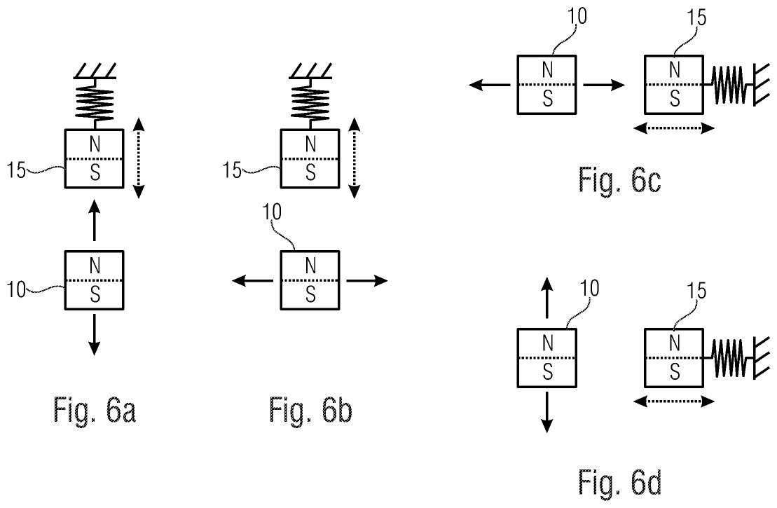

FIGS. 6a-d each show different supports of the permanent-magnetic structures 10 and 15 or of the individual permanent-magnetic elements of the permanent-magnetic structures 10 and 15, respectively, to explain which linear displacements (solid arrow) result in which linearly acting forces or deflections (broken-line arrow).

In FIGS. 6a and 6c, input displacement and deflection or force act in parallel. The vertical-vertical coupling (FIG. 6a) and the lateral-lateral coupling (FIG. 6c) are shown. In contrast, in the geometries shown in FIGS. 6b and 6d, the deflection or force perpendicular to the input displacement is used, i.e. there is a rotation of the effective direction by 90°, namely the lateral-vertical coupling (FIG. 6b) and the vertical-lateral coupling (FIG. 6d).

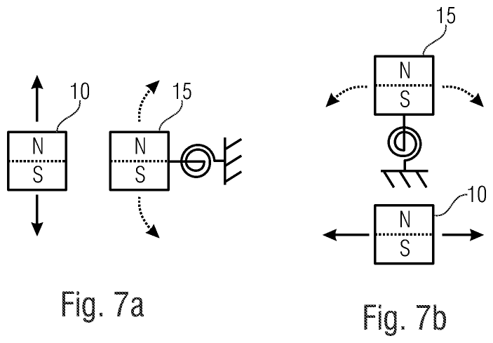

Taking advantage of the transmitted torque, other geometries can be found for converting a linear motion of the permanent-magnetic structure 10 into a tilting motion of the permanent-magnetic structure 15. Examples of this are shown in FIGS. 7a and 7b, assuming that the element 10 is translationally movable while the element 15 is rotationally movable. The geometry in FIG. 7a transforms a vertical displacement of element 10 into a tilting of element 15, while the geometry in FIG. 7b transforms a lateral displacement of element 10 into a tilting of element 15. Particularly in the case of FIG. 7b, it should be mentioned that the support can be arranged between the elements 10 and 15, for example.

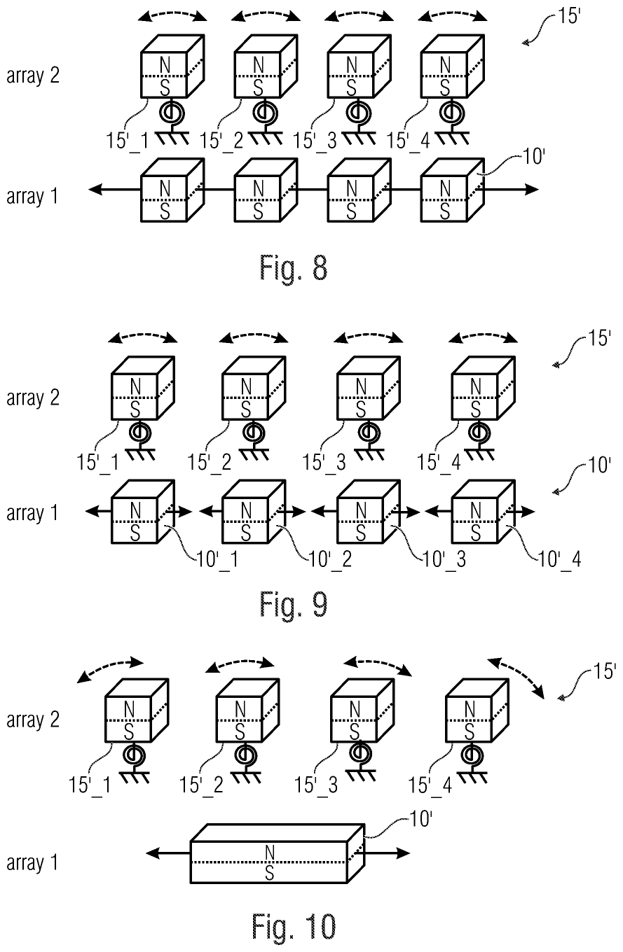

The geometries shown here are abstractions of the principle of action to classify the possible implementations of magnetic force coupling. The magnets are to be seen as placeholders for arbitrarily implemented permanent-magnetic microstructures. In addition to variations in shape and aspect ratio, designs using micromagnet arrays are particularly advantageous. FIGS. 8, 9 and 10 illustrate three examples. The arrays are marked with reference signs 10′/10 and 15′, in analogy to FIG. 4 and FIG. 3. In the following consideration, it is assumed that always the array 10′ (in the case of FIG. 10, the element 10′) is moved translationally and in such a way that the individual elements of the array 10′ are displaced relative to the individual elements of the array 15′. The elements of the array 15′ are each individually rotationally/individually supported. In the case of the array 10′ of FIG. 8, the array is assumed to have elements that are rigidly connected/fixed to one another (so that synchronous movement of the micromagnets of the array 15′ is achieved), whereas in the case of the array 10′ of FIG. 9, the array is one in which the individual elements are independently movable (e.g. by multiple (external) MEMS actuators). In FIG. 10, the array 10′ has a single magnet with an enlarged cross-section. This single magnet 10′ is configured to interact with all elements 15′_1 to 15′_4, e.g. by being moved along all elements 15′_1 to 15′_4. In contrast, in the embodiments of FIGS. 8 and 9, there may be an association of the elements of the array 10 with the elements of the array 15 (cf. FIG. 9 10′_1 with 15′_1, 10′_2 with 15′_2, 10′_3 with 15′_3, and 10′_4 with 15′_4).

In FIG. 8, a displacement of the array 10′, whose micromagnets are rigidly fixed within the array, causes a synchronous tilting of the micromagnets of the array 15′, whose micromagnets are not connected to one another. In contrast, in the embodiment shown in FIG. 9, the micromagnets of array 10′ can be displaced individually, resulting in a corresponding individual tilting of the micromagnets of array 15′.

In FIG. 10, the structures 10′ and 15′ are not identical in terms of the number, size and arrangement of the micromagnets. A displacement of the micromagnet 10′ results in an individual tilting of the micromagnets of the array 15′ according to the three-dimensional course of the magnetic field.

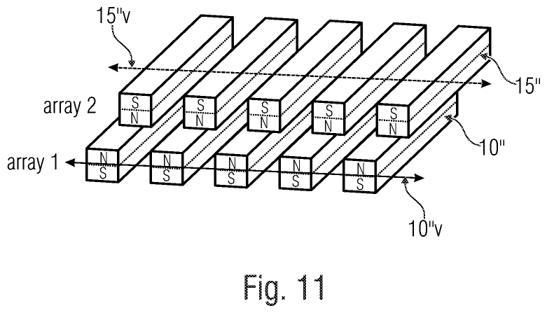

Furthermore, the implementations of the magnetic force coupling are not limited to a parallel magnetization of the magnetic structures 10′/15′ or 10/15 used. For the force couplings listed abstractly in FIGS. 6 and 7, for example, an opposite movement can be realized with an opposite magnetization. In particular, for the array design 10″ or 15″ for force modulation, an opposite magnetization as shown in FIG. 11 can be exploited to replace the superimposed attraction visible in FIG. 5 with a superimposed repulsion. This is particularly important when a relatively soft spring is used to vertically guide the array 15/15′/15″ to achieve high deflections. A superimposed attractive force can outweigh the resetting spring force and pull the magnets into contact. The repulsion associated with the opposite magnetization eliminates such an instability. It should be noted that due to the opposite magnetization, the equilibrium position is located at an offset of one edge length.

According to embodiments, the magnetic coupling is not limited to a transmission of forces through free space or ambient atmosphere, as assumed in the previous embodiments. Most of the materials used in microsystem technology have a negligible influence on the magnetic field. This allows the advantage of contactless force transmission to be further exploited in order to transmit forces through existing structures that exclude contact mechanical transmission, for example.

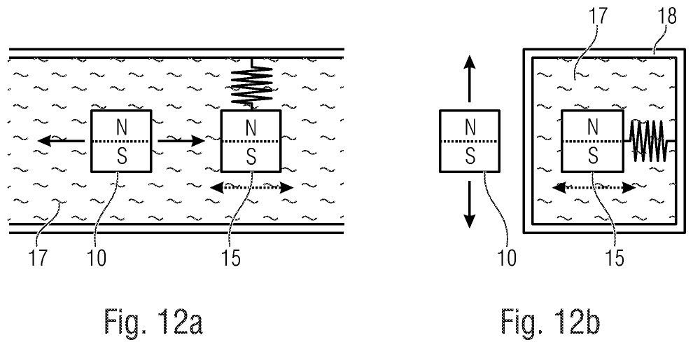

Such an example of force coupling within a medium 17 is shown in FIG. 12a. The embodiment shown here corresponds to the embodiment in FIG. 6c, as far as the movement pattern is concerned (solid arrow movement, e.g. caused externally or by an actuator; broken-line arrow reaction).

Another example of a transmission of a force or a mechanical signal from outside into a closed system (cf. system boundary 18, within which a fluid or a gas atmosphere 17 (alternatively evacuated atmosphere/vacuum) may prevail) is shown in FIG. 12b. The magnetic coupling allows force transmission through the materials used in microsystem technology. In this respect, force coupling can be realized in the fluid 17 or through hermetic encapsulations 18.

It should be noted at this point that, of course, magnetic coupling is not limited to the boundaries of a component. The concepts described can also be used for contactless transmission of forces or displacements between different components. A special case here is the coupling of a microsystem with a macroscopic component by means of permanent-magnetic structures for the transmission of forces or displacements. Here again, the transmission through existing structural materials (which serve, for example, to encapsulate the components, as shown in FIG. 12b (cf. encapsulation 18)) comes into play. In particular, this enables applying macroscopic drives to drive microsystems.

Embodiments may be applied in a variety of microelectromechanical systems where drive or sensor concepts have previously reached their limits. The invention described here allows the direction of force and deflection to be redirected, and geometric restrictions can thus be mitigated. In particular, the use as a lateral-vertical transducer in laterally acting drives for generating vertical deflections is especially advantageous. Applications that entail large vertical deflections, such as micromirrors and/or microloudspeakers, for example, can benefit from this.

Even though the above embodiments have always assumed a movement of the second array 10 as a result of a movement of the first array 15, it should be noted at this point that instead of the movement of the second array 10, an actuation in the sense of coupling in a force can also take place.

Further embodiments are explained below:

According to a first embodiment, the system comprises at least two spaced-apart permanent-magnetic arrangements comprising individual micromagnets or an array of micromagnets, wherein a change in position of the micromagnets of one permanent-magnetic arrangement, thanks to the magnetic force coupling, causes a change in position of the micromagnets in a second permanent-magnetic arrangement or a change in the forces acting on the second permanent-magnetic arrangement.

According to embodiments, the change in position of the micromagnets of the first permanent-magnetic arrangement is caused by one or more micromechanical actuators integrated at substrate level or by an external device.

According to embodiments, the individual micromagnets within a permanent-magnetic arrangement are rigidly connected to one another.

According to alternative embodiments, the individual micromagnets within a permanent-magnetic arrangement are independently movable (i.e., individually coupled).

According to an embodiment, the number, shape, size and arrangement of the micromagnets of the at least two permanent-magnetic arrangements may differ (cf. FIG. 10).

According to embodiments, the elements of the permanent-magnetic arrangement(s) explained above are arranged in such a way that a kind of comb-shaped structure is formed. There may be a repeat spacing of the individual elements, for example, wherein this may be constant, for example (range between 10 μm and 300 μm). Further, according to additional embodiments, it is also possible to have a periodicity with a repeat spacing in a second direction, so that e.g. instead of comb-shaped structures in two dimensions, regularly arranged cubes are formed per array.

Another embodiment relates to a method for manufacturing the permanent-magnetic structures. The permanent magnets or micromagnet arrays are manufactured on planar substrates by agglomeration of powder using, for example, ALD in a parallel manufacturing process. In accordance with further embodiments, another type of deposition or another manufacturing method, such as sintering, is of course also conceivable. Even though embodiments of the present invention have been explained in particular with reference to apparatus, it should be noted that the description of an apparatus feature can be understood to be a description of a method feature.

While this invention has been described in terms of several embodiments, there are alterations, permutations, and equivalents which will be apparent to others skilled in the art and which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

### CITED DOCUMENTS

[1] R. Legtenberg et al, “Comb-drive actuators for large displacements”, J. Micromech. and Microeng. no. 6, 1996.
[2] A. P. Lee et al, “Electrostatic comb drive for vertical actuation”, Proc. SPIE 3224 Micromachined Devices and Components III, 1997.
[3] D. Hah et al, “Theory and Experiments of Angular Vertical Combb-Drive Actuators for Scanning Micromirrors,” J. Selected Topics in Quantum Electronics, No. 10, 2004.
[4] J. A. Yeh et al. “Large rotation actuated by in-plane rotary comb-drives with serpentine spring suspension,” J. Micromech. and Microeng. no. 15, 2005.
[5] J. E. Wong et al, “An electrostatically-actuated MEMS switch for power applications”, Proc. IEEE MEMS Conf., Miyazaki, Japan, 2000.
[6] X. M. Zhang et al, “A study of the static characteristics of a torsional micromirror,” Sensors and Actuators A: Physical, no. 90, 2001.
[7] J. D. Grade et al, “Design of Large Deflection Electrostatic Actuators,” J. Microelectromech. sys, no. 12, 2003.
[8] N. Takeshima et al, “Electrostatic Parallelogram Actuators”, Proc. IEEE Transducers Conf., San Francisco, Calif., USA, 1991.
[9] X. T. Huang et al, “A micromotion amplifier”, Proc. IEEE MEMS Conf., San Diego, Calif., USA, 1996.
[10] G. Krishnan et al, “Evaluation and Design of Displacement-Amplifying Compliant Mechanisms for Sensor Applications,” J. Mechanical Design, no. 130, 2008.
[11] I. Zeimpekis et al, “Characterization of a Mechanical Motion Amplifier Applied to a MEMS Accelerometer.” J. Microelectromech. Sys, no. 21, 2012.
[12] J.-C. Tsai et al, “Design, Fabrication, and Characterization of a High Fill-Factor, Large Scan-Angle. Two-Axis Scanner Array Driven by a Leverage Mechanism,” J. Microelectromech. Sys, no. 15, 2006.
[13] M. S. Rodgers et al, “Designing and operating electrostatically driven microengines,” University of North Texas Libraries, Albuquerque, 1998.
[14] C. T.-C. Nguyen, “Frequency-selective MEMS for miniaturized low-power communication devices” IEEE Transactions on Microwave Theory and Techniques, 1999.
[15] D. Weinstein et al, “Mechanical Coupling of 2D Resonator Arrays for MEMS Filter Applications”, IEEE International Frequency Control Symposium, 2007.
[16] S. Pourkamali et al, “Electrically coupled MEMS bandpass filters Part II. Without coupling element,” Sensors and Actuators A, no. 122, 2005.
[17] H. Sasaki et al, “A force transmission system based on a tulip-shaped electrostatic clutch for haptic display devices”, J. Micromech. and Microeng., no. 16, 2006.
[18] D. Isarakorn et al, “Energy scavenging from a rotating gear using an impact type piezoelectric energy scavenger”, Patent Application WO 2012/164545 A1.
[19] I. Aoyagi et al, “A raster-output 2D MEMS scanner with an 8×4 mm mirror for an automotive time-of-flight image sensor”, Proc. IEEE Transducers Conf., Barcelona, Spain, 2013.
[20] C. L. Arrasmith et al, “MEMS-based handheld confocal microscope for in-vitro skin imaging”, Optics Express, vol. 18, no. 4, 2010.
[21] M. Nakano et al, “Magnetic properties of Pr—Fe—B thick-film magnets deposited on Si substrates with glass buffer layer”, AIP Advances 8, 2018.
[22] D. Le Roy et al, “Fabrication and characterization of polymer membranes with integrated arrays of high performance micro-magnets”, Materials Today Communications, 6, 2016.
[23] E. S. Leland et al, “A MEMS AC current sensor for residential and commercial electricity end-use monitoring”, J. Micromech. and Microeng., 19, 2009.
[24] O. D. Oniku et al, “High-energy-density permanent micromagnets formed from heterogeneous magnetic powder mixtures”, Proc. IEEE MEMS Conf., Paris, France, 2012.
[25] T. Lisec et al, “A Novel fabrication technique for MEMS based on agglomeration of powder by ALD”, J. Microelectromech. Sys, vol. 26, no. 5, 2017.
[26] F. Lofink et al, “Magnetically driven energy-harvester with monolithically integrated high-energy-density magnets”, Proc. IEEE Transducers Conf., Kaohsiung, Taiwan, 2017.
[27] publication of application US 20140152134 A1, “Energy harvesting devices.”
[28] T. Reimer et al, “Temperature-stable NdFeB micromagnets with high-energy density compatible with CMOS back end of line technology”, MRS Advances, No. 1, 2016.
[29] publication of application DE102016215616 A1, “Verfahren zum Herstellen einer magnetischen Struktur” (Method of manufacturing a magnetic structure).

1. A MEMS system, comprising:
a first permanent-magnetic microstructure movable along a first direction;
a second permanent-magnetic microstructure arranged to be spaced apart from the first permanent-magnetic microstructure, wherein, by moving the first permanent-magnetic microstructure along the first direction, the second permanent-magnetic microstructure or one or more elements of the second permanent-magnetic microstructure are either moved or actuated in a second direction or undergo rotation;
wherein the first permanent-magnetic microstructure is formed by a first array comprising a plurality of permanent-magnetic elements; or wherein the second permanent-magnetic microstructure is formed by a second array comprising a plurality of the permanent-magnetic elements; and
wherein the plurality of the permanent-magnetic elements of the first or second array are rigidly connected to one another so that they are similarly moved or actuated as a result of a movement of the first permanent-magnetic microstructure along the second direction.

2. The MEMS system according to claim 1, wherein the first permanent-magnetic microstructure is formed by an array; and wherein the second permanent-magnetic microstructure is formed by an array.

3. The MEMS system according to claim 2, wherein each element of the first or the second array comprises an edge length in the range of 10 μm to 2 mm, advantageously in the range of 20 μm to 1000 μm, particularly advantageously in the range of 30 μm to 800 μm; and/or
wherein the respective array comprises a repeat spacing of the elements in the range of 10 μm to 4 mm, advantageously in the range of 20 μm to 1500 μm, particularly advantageously in the range of 50 μm 1000 μm.

4. The MEMS system according to claim 1, wherein the first and second permanent-magnetic microstructures are configured such that, over an entire range of motion of the first and second permanent-magnetic structures, a spacing is in a range of 1 μm to 5 mm or in a range of 5 μm to 2000 μm or in a range of 10 μm to 1000 μm.

5. The MEMS system according to claim 1, wherein the first permanent-magnetic microstructure is magnetized in parallel with or is magnetized in opposite direction to the second permanent-magnetic microstructure.

6. The MEMS system according to claim 1, wherein the second direction is different from the first direction; or wherein the second direction is perpendicular to the first direction.

7. The MEMS system according to claim 1, wherein the second permanent-magnetic microstructure or the one or more elements of the second permanent-magnetic microstructure forming the second array are each rotated about an axis of rotation that is perpendicular to the first direction.

8. The MEMS system according to claim 1, wherein the MEMS system comprises a support for the first permanent-magnetic structure that restricts movement or actuation perpendicular to the first direction.

9. The MEMS system according to claim 1, wherein the second permanent-magnetic microstructure or the one or more elements of the second permanent-magnetic microstructure are supported by means of a support which restricts movement or actuation perpendicular to the second direction or which only permits rotation about a rotation point or points defined by the second permanent-magnetic microstructure.

10. The MEMS system according to claim 1, wherein the first permanent-magnetic microstructure or one or more elements of the first permanent-magnetic microstructure and/or the second permanent-magnetic microstructure or the one or more elements of the second permanent-magnetic microstructure extend along a third direction which is perpendicular to the first and second directions.

11. The MEMS system according to claim 1, wherein the plurality of permanent-magnetic elements are individually supported such that they are similarly moved or actuated or undergo a similar rotation as a result of a movement of the first permanent-magnetic microstructure along the second direction.

12. The MEMS system according to claim 1, wherein the plurality of permanent-magnetic elements are individually supported such that the plurality of permanent-magnetic elements undergo individual movement or actuation in response to the movement of the first permanent-magnetic structure.

13. The MEMS system according to claim 1, wherein the first permanent-magnetic structure comprises a singular number or a plurality of permanent-magnetic elements facing the plurality of permanent-magnetic elements of the second permanent-magnetic structure; or
wherein the first permanent-magnetic structure comprises a plurality of permanent-magnetic elements facing the same plurality of permanent-magnetic elements of the second permanent-magnetic microstructure.

14. The MEMS system according to claim 1, further comprising a micromechanical actuator connected or coupled to the first permanent-magnetic structure, wherein the micromechanical actuator is configured to move the first permanent-magnetic structure along the first direction.

15. The MEMS system according to claim 1, wherein the first permanent-magnetic microstructure and the second permanent-magnetic microstructure are formed within a substrate.

16. The MEMS system according to claim 15, wherein the first direction extends laterally along the substrate; and wherein the second direction extends laterally along the substrate or perpendicular to the substrate.

17. The MEMS system according to claim 1, wherein the first or second permanent-magnetic microstructure is arranged in a chamber such that the first permanent-magnetic microstructure is encapsulated with respect to the second permanent-magnetic microstructure.

18. A method of manufacturing a MEMS system according to claim 1, comprising:
agglomeration of powder by means of atomic layer deposition or by means of deposition to form the first and/or the second permanent-magnetic microstructure or to form the one or more elements of the first and/or the second permanent-magnetic microstructure.
